(19) United States
(12) Patent Application Publication
(10) Pub. No.: US 2005/0145843 A1
(43) Pub. Date: Jul. 7, 2005

(54) Thin film transistor and method of manufacturing the same

(75) Inventors: Huaxiang Yin, Gyeonggi-do (KR); Takashi Noguchi, Gyeonggi-do (KR); Wenxu Xianyu, Gyeonggi-do (KR); Do-young Kim, Gyeonggi-do (KR)

Correspondence Address: BURNS DOANE SWECKER & MATHIS L L P, POST OFFICE BOX 1404, ALEXANDRIA, VA, 22313-1404, US

(73) Assignee: Samsung Electronics Co., Ltd., Gyeonggi-do (KR)

(21) Appl. No.: 11/013,398

(22) Filed: Dec. 17, 2004

(30) Foreign Application Priority Data
Dec. 17, 2003 (KR) 10-2003-0092611

(51) Int. Cl. H01L 29/04; H01L 21/00

(52) U.S. Cl. 257/57; 438/149

(57) ABSTRACT

A thin film transistor and a method of manufacturing the same are provided. The thin film transistor includes a substrate; a buffer layer formed on the substrate; a source and a drain spaced apart from each other on the buffer layer; a channel layer formed on the buffer layer to connect the source and the drain with each other; and a gate formed on the buffer layer to be spaced apart from the source, the drain and the channel layer.

### BACKGROUND OF THE INVENTION

Priority is claimed to Korean Patent Application No. 2003-92611, filed on Dec. 17, 2003, in the Korean Intellectual Property Office, the disclosure of which is incorporated herein in its entirety by reference.

1. Field of the Invention

The present invention relates to a semiconductor device and a method of manufacturing the same, and more particularly, to a thin film transistor and a method of manufacturing the same.

2. Description of the Related Art

A method of manufacturing a thin film transistor includes a film deposition process and a patterning process for forming a predetermined shape of a deposited film, as with methods of manufacturing a semiconductor device generally. Each process step in fabricating the thin film transistor is directly related to productivity and manufacture cost of the thin film transistor. Accordingly, as the manufacture process steps increase in number, the productivity is lowered and the manufacture cost is increased. To the contrary, the productivity is increased and the manufacture cost is lowered when the number of process steps are reduced, generally.

Even when the entire manufacture process of the thin film transistor is simple, if masks, which are used in each process of the TFT, are increased in number, the manufacture cost relating to the thin film transistor is increased.

Therefore, it is desirable to reduce the number of the masks, which are used in each of the manufacture processes, together with the number of the manufacture process steps of the thin film transistor, so as to increase the productivity and reduce the prime cost.

FIG. 1 shows a conventional coplanar thin film transistor.

Referring to FIG. 1, a buffer layer 10 is formed on a substrate 8, and a poly-silicon film 12 is formed on the predetermined region of the buffer layer 10. The poly-silicon film 12 includes source and drain regions 12a and 12c doped with n+ type conductive impurities and a channel region 12b. The channel region 12b is provided between the source and drain regions 12a and 12c. A gate insulating film 14 and a gate electrode 16 are sequentially formed on the channel region 12b of the poly-silicon film 12. An interlayer insulating layer 18 is formed on the buffer layer 10 to cover the poly-silicon film 12, the gate insulating film 14 and the gate electrode 16. The interlayer insulating layer 18 has first and second contact holes 19 and 20 for respectively exposing the source and drain regions 12a and 12c. Additionally, a first electrode 22 and a second electrode 24 are formed on the interlayer insulating layer 18 to fill the first contact hole 19 and the second contact hole 20, respectively.

FIG. 2 shows a conventional top gate staggered thin film transistor.

Referring to FIG. 2, a buffer layer 10 is formed on a substrate 8. Separated source and drain electrodes 30 and 32 are formed on the buffer layer 10. A poly-silicon film 34 used as a channel region is formed on the buffer layer 10 between the source and drain electrodes 30 and 32. The poly-silicon film 34 extends on the source and drain electrodes 30 and 32. N⁺ type conductive impurities are injected into the source and drain regions 34a and 34c, which are respectively in contact with the source and drain electrodes 30 and 32. A silicon oxide film 36 used as a gate insulating film is formed on the poly-silicon film 34, and a chromium gate electrode 38 is formed on the silicon oxide film 36.

FIG. 3 shows a conventional bottom gate staggered thin film transistor.

Referring to FIG. 3, a buffer layer 10 is formed on a substrate 8, and a chromium gate electrode 40 is formed on the predetermined region of the buffer layer 10. A nitride film (Si₃N₄) 42, which covers the chromium gate electrode 40, and a first silicon oxide film 44 are sequentially formed on the buffer layer 10. A poly-silicon film, which is used as a channel region, is formed on the first silicon oxide film 44. A second silicon oxide film 48 is formed on the predetermined region of the poly-silicon film 46, which faces with the chromium gate electrode 40. Additionally, a poly-silicon film 49 is formed on the poly-silicon film 46 formed on the left of the chromium gate electrode 40. The poly-silicon film 49 is used as a source region, and is doped with n⁺ conductive impurities. Additionally, a poly-silicon film 50 is formed on the poly-silicon film 46 formed on the right of the chromium gate electrode 40. The poly-silicon film 50 is used as a drain region, and is doped with the n⁺ conductive impurities. Source and drain electrodes 52 and 54 are formed on the two poly-silicon films 49 and 50, respectively.

As described above, the conventional TFTs shown in FIGS. 1 through 3 require at least four masks and more than ten processes until the buffer layer 10 and the first and second electrodes 22 and 24 are formed, the buffer layer 10 and the chromium gate electrode 38 are formed, or the buffer layer 10 and the source and drain electrodes 52 and 54 are formed.

### SUMMARY OF THE INVENTION

The present invention provides a Thin Film Transistor (TFT) for allowing the numbers of process and mask to be reduced, thereby reducing a manufacture cost.

Also, the present invention provides a method of manufacturing a TFT.

According to an aspect of the present invention, there is provided a TFT including: a substrate; a buffer layer which is formed on the substrate; a source and a drain which are spaced apart from each other on the buffer layer; a channel layer which is formed on the buffer layer to connect the source and the drain with each other; and a gate which is formed on the buffer layer to be spaced apart from the source, the drain and the channel layer.

The source may include first and second source conductive films that are sequentially deposited. The drain may include first and second conductive films that are sequentially deposited.

The gate may be comprised of first and second gates that are made symmetric, centering on the channel layer, and at least any one of the first and second gates may include two conductive films that are sequentially deposited.

The channel layer may be extended on the source and the drain.

The channel layer may have both ends covered with portions of the source and the drain.

The channel layer may be formed of one of silicon (Si), silicon germanium (SiGe) and germanium (Ge).

An insulating film may be provided between the gate and the channel layer.

The substrate may be one of a crystal substrate, an aluminum oxide substrate, a glass substrate and a plastic substrate.

The first gate and the second gate may be disposed in the vicinities of the source and the drain, respectively.

According to another aspect of the present invention, there is provided a method of manufacturing a thin film transistor (TFT), the method including the steps of: forming a buffer layer on a substrate; forming a channel layer on the buffer layer; forming a conductive film on the buffer layer to cover the channel layer; and patterning the conductive film to form a source and a drain, which cover both ends of the channel layer, on the buffer layer and concurrently form a gate to be spaced apart from the channel layer, the source and the drain.

After the formation of the gate, the method may further include the steps of: forming an interlayer insulating layer which fills a space between the gate and the channel layer while covering the gate, the source and the drain; and forming a contact hole for exposing the gate, the source and the drain in the interlayer insulating layer.

According to a further another aspect of the present invention, there is provided a method of manufacturing a thin film transistor (TFT), the method including: forming a buffer layer on a substrate; forming a conductive film on the buffer layer; patterning the conductive film to separately form a source, a drain and a gate on the buffer layer; and forming a channel layer for connecting the source with the drain on the buffer layer.

Herein, the forming of the channel layer can further include: forming an amorphous silicon film covering the gate, the source and the drain on the buffer layer; crystallizing the amorphous silicon film; and patterning the crystallized silicon film in a shape connecting the source with the drain. At this time, the amorphous silicon film may be crystallized using a SPC (Solid-Phase Crystallization) method or an ELA (Excimer Laser Annealing) method.

After the forming of the channel layer, the method may further include: forming an interlayer insulating layer which fills a space between the gate and the channel layer while covering the gate, the source and the drain; and forming a contact hole for exposing the gate, the source and the drain in the interlayer insulating layer.

In the two methods of manufacturing the TFT, the substrate may be one of a crystal substrate, an aluminum oxide substrate, a glass substrate and a plastic substrate.

Additionally, first and second conductive films may be sequentially deposited to form the conductive film.

Further, the channel layer may be formed of one of silicon (Si), silicon germanium (SiGe) and germanium (Ge). The gate can be comprised of first and second gates, which are symmetric or asymmetric centering on the channel layer. In case where the first and second gates are made symmetric, the first gate may be disposed closely to the source, and the second gate may be disposed closely to the drain.

Furthermore, the channel layer also may be the doped poly-silicon layer.

In the method of manufacturing the TFT according to the present invention, since the number of masks being used is reduced and the number of total processes is reduced, a manufacture cost can be reduced. Additionally, since the source, the drain, the gate and the channel can be all formed on the same plane, they can be designed more flexibly. Further, the present invention can be also applied to a poly-silicon TFT, which is processed in a high temperature process.

### BRIEF DESCRIPTION OF THE DRAWINGS

The above and other features and advantages of the present invention will become more apparent by describing in detail exemplary embodiments thereof with reference to the attached drawings in which:

FIG. 1 is a section view illustrating a conventional coplanar thin film transistor;

FIG. 2 is a section view illustrating a conventional top gate staggered thin film transistor;

FIG. 3 is a section view illustrating a conventional bottom gate staggered thin film transistor;

FIG. 4 is a plan view illustrating a thin film transistor according to a first embodiment of the present invention;

FIG. 5 is a plan view illustrating a thin film transistor of FIG. 4 having asymmetric first and second gates;

FIG. 6 is a section view taken along the line 6-6′ of FIG. 4;

FIG. 7 is a section view taken along the line 7-7′ of FIG. 4;

FIG. 8 is a perspective view illustrating a thin film transistor of FIG. 4;

FIG. 9 is a plan view illustrating a thin film transistor according to a second embodiment of the present invention;

FIG. 10 is a plan view illustrating a thin film transistor of FIG. 9 having asymmetric first and second gates;

FIG. 11 is a section view taken along the line 11-11′ of FIG. 9;

FIG. 12 is a section view taken along the line 12-12′ of FIG. 9;

FIG. 13 is a perspective view illustrating a thin film transistor of FIG. 9;

FIGS. 14 through 18 are section views illustrating a method of manufacturing a thin film transistor according to a first embodiment of the present invention; and

FIGS. 19 through 23 are section views illustrating a method of manufacturing a thin film transistor according to a second embodiment of the present invention.

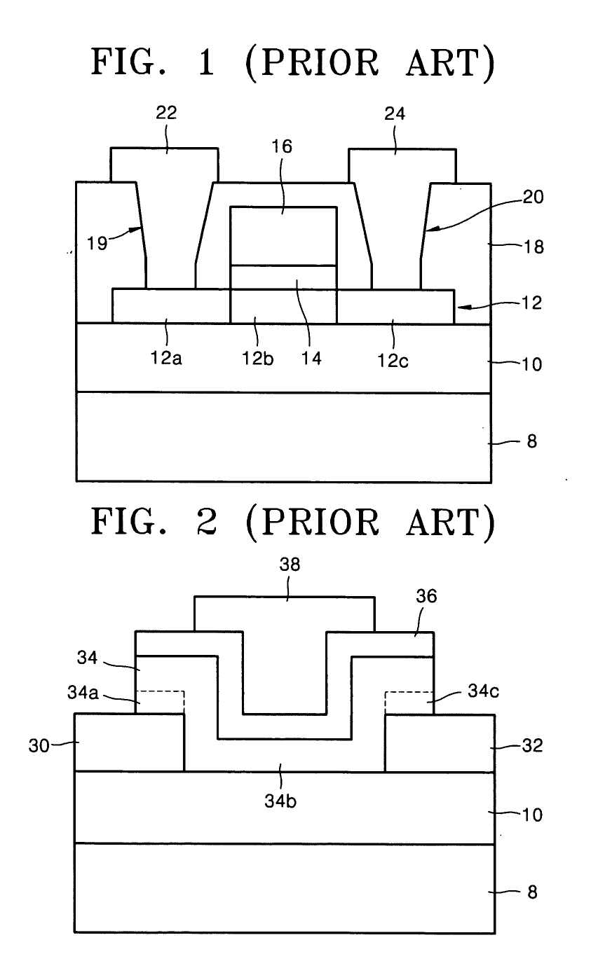

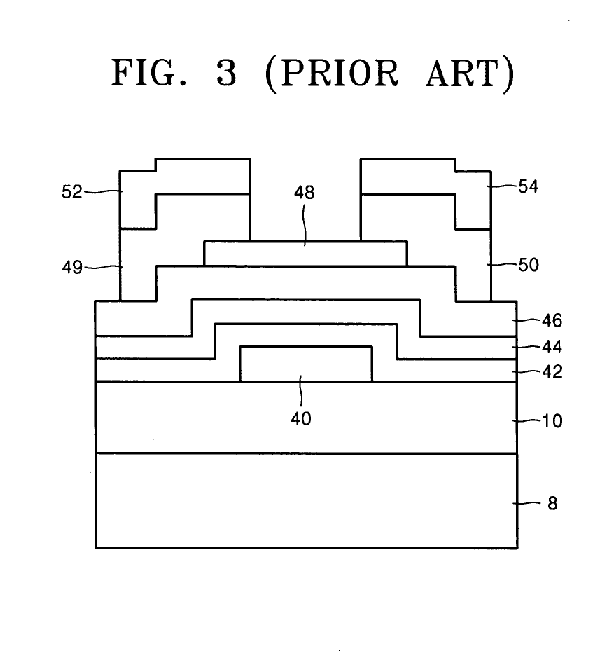

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their description will be omitted.

First of all, a thin film transistor (TFT) according to an embodiment of the present invention is described.

### First Embodiment

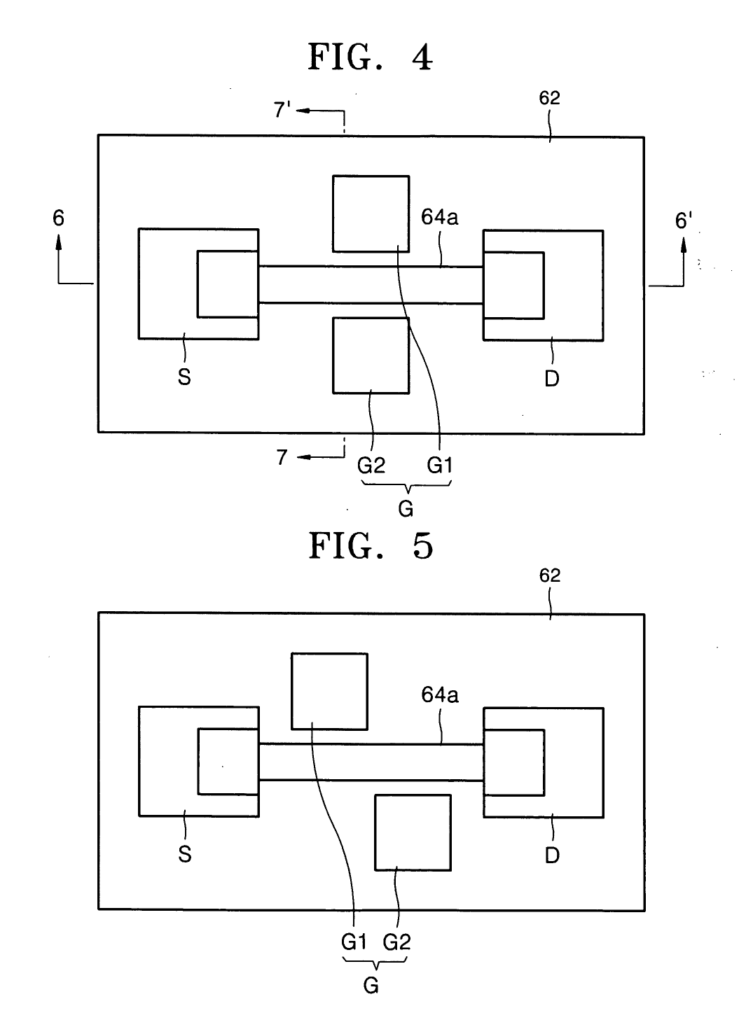

FIG. 4 shows a thin film transistor according to the first embodiment of the present invention (hereinafter, referred to as “first TFT).

Referring to FIG. 4, a channel layer 64a is formed on a lower layer 58, and a source S and a drain D are formed on the lower layer 58 at both ends of the channel layer 64a. The channel layer 64a can be formed of silicon (Si), silicon germanium (SiGe) or germanium (Ge). The source S and the drain D may be formed of the same conductive material, but can be formed of different conductive materials. The gate G is spaced apart from the channel layer 64a, the source S and the drain D. A gate insulating film (not shown) such as a silicon oxide film (SiO₂) can be formed between the gate (G) and the channel layer 64a. The gate G is comprised of the first and second gates G1 and G2. The first and second gates G1 and G2 are made symmetric with each other centering on the channel layer 64a, but can be asymmetric. As shown in FIG. 5, the first gate G1 can be disposed closely to the source S, and the gate G2 can be disposed closely to the drain D, for instance. The first and second gates G1 and G2 identically influence the channel layer 64a. Therefore, the gate G may be comprised of any one of the first and second gates G1 and G2. To the contrary, the gate G may also include third and fourth gates in addition to the first and second gates G1 and G2. The first and second gates G1 and G2 may be formed of the same conductive material as the source S or the drain D, but can be formed of different conductive materials.

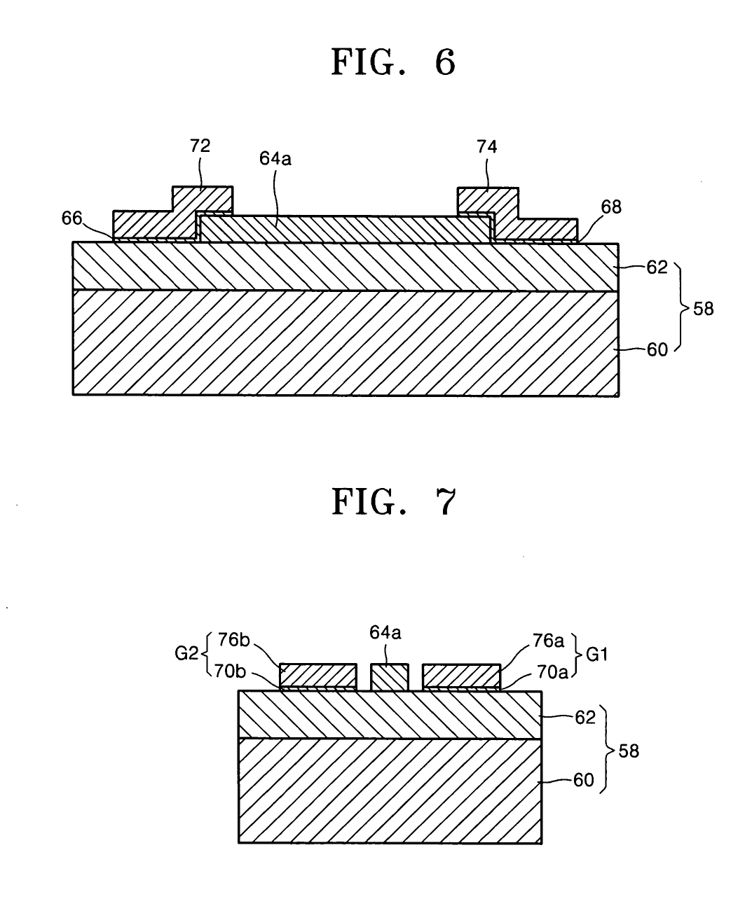

FIG. 6 is a sectional view taken along the line 6-6′ of FIG. 4.

Referring to FIG. 6, a substrate 60 and a buffer layer 62 are sequentially deposited to form the lower layer 58. The substrate 60 may be a silicon substrate, but can be a crystal substrate, an aluminum oxide substrate, a glass substrate or a plastic substrate. The buffer layer 62 functions to reduce stress, which is caused by the difference of thermal expansion coefficients between the substrate 60 and an upper layer formed on the substrate 60. The buffer layer 62 can be formed of silicon oxide. The portions of the source S and the drain D are extended on the channel layer 64a. The source S includes first and second source conductive films 66 and 72, which are sequentially deposited, and the drain D includes first and second drain conductive films 68 and 74, which are sequentially deposited. It can be understood that the first and second gate conductive films 70a and 76a are sequentially deposited to form the first gate G1. The first source conductive film 66, the first drain conductive film 68 and the first gate conductive film 70a can be formed of n+ doped poly-silicon, for example. Additionally, the second source conductive film 72, the second drain conductive film 74 and the second gate conductive film 76a may be formed of chromium (Cr), but can be formed of a different metal such as molybdenum tungsten (MoW) or aluminum neodymium (AlNd).

FIG. 7 is a sectional view taken along the line 7-7′ of FIG. 4.

Referring to FIG. 7, the first and second gates G1 and G2 and the channel layer 64a are all formed on the buffer layer 62, and have the same thickness. However, the channel layer 64a and the first and second gates G1 and G2 can have different thicknesses from each other. The second gate G2 includes a third gate conductive film 70b and a fourth gate conductive film 76b, which are deposited in sequence. The third gate conductive film 70b can be formed identically with the first gate conductive film 70a, and the fourth gate conductive film 76b can be formed identically with the second gate conductive film 76a.

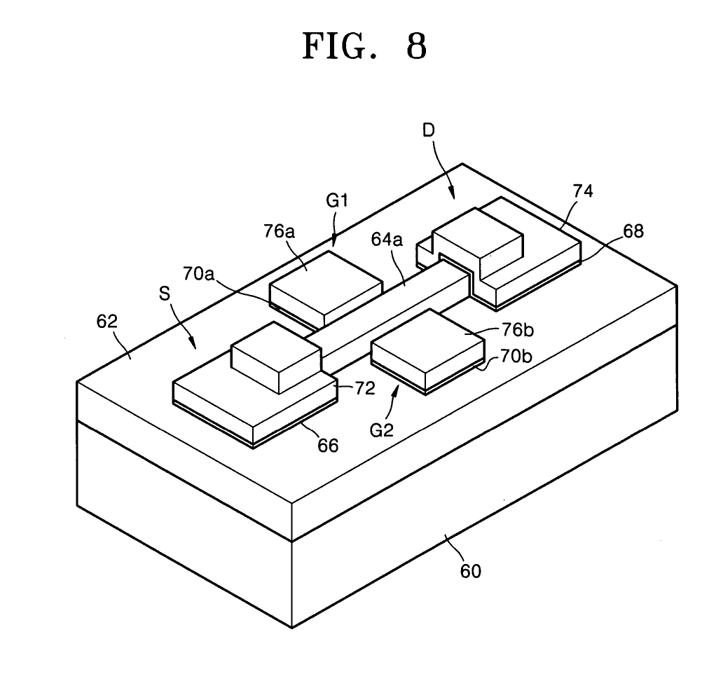

FIG. 8 is a perspective view illustrating the thin film transistor of FIG. 4.

### Second Embodiment

Descriptions for the same elements as those of the first TFT by the present invention are omitted, and the same reference numeral or symbol is used for the same elements.

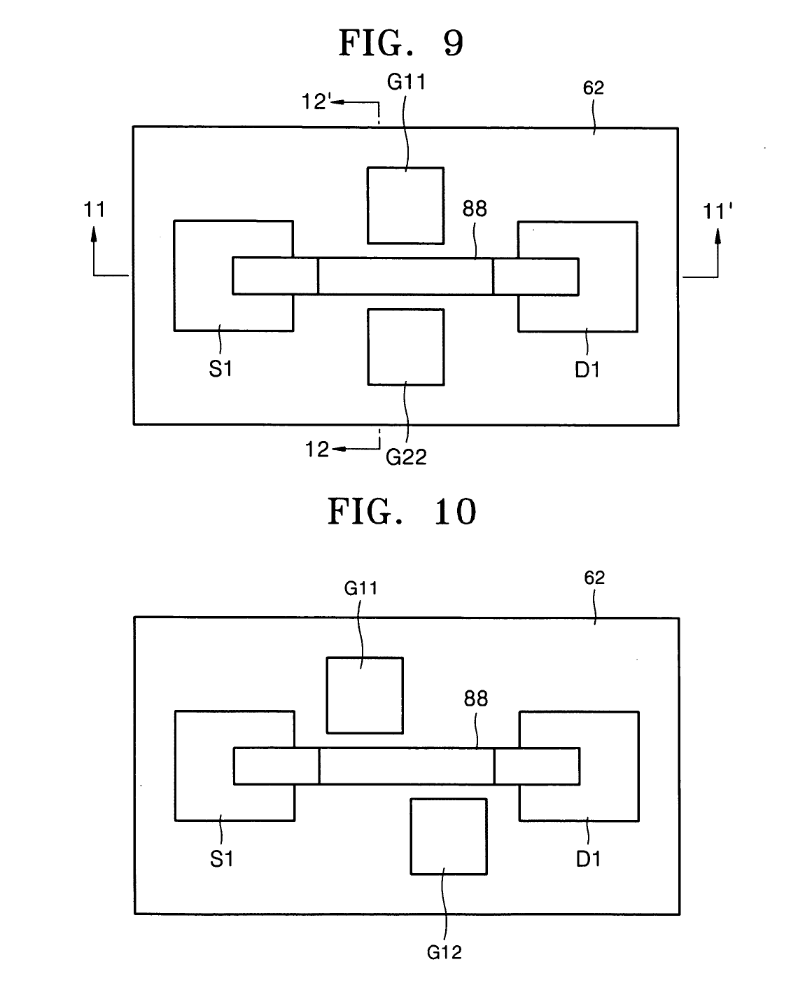

FIG. 9 is a plan view illustrating elements included in the thin film transistor according to the second embodiment of the present invention (Hereinafter, referred to as “second TFT”).

Referring to FIG. 9, a channel layer 88 is formed on a lower layer 58. A source S1 is connected to one end of the channel layer 88, and a drain D is connected to the other end of the channel layer 88. First and second gates G11 and G22 are provided on the lower layer 58 to be spaced apart from the channel layer 88 at a predetermined interval. The first and second gates G11 and G22 are made symmetric centering on the channel layer 88, which is disposed between the source S1 and the drain D1, in this example. The first and second gates G11 and G22 may be asymmetric centering on the channel layer 88. For example, as shown in FIG. 10, the first gate G1 may be provided in the vicinity of the source S1, and the second gate G22 may be provided in the vicinity of the drain D1. A gate insulating film (not shown) may be provided between the first and second gates G11 and G22 and the channel layer 88, but is not illustrated for convenience. The channel layer 88 is formed of poly-silicon in this example. The channel layer 88 can be formed of silicon (Si), silicon germanium (SiGe) or germanium (Ge) in addition to poly-silicon.

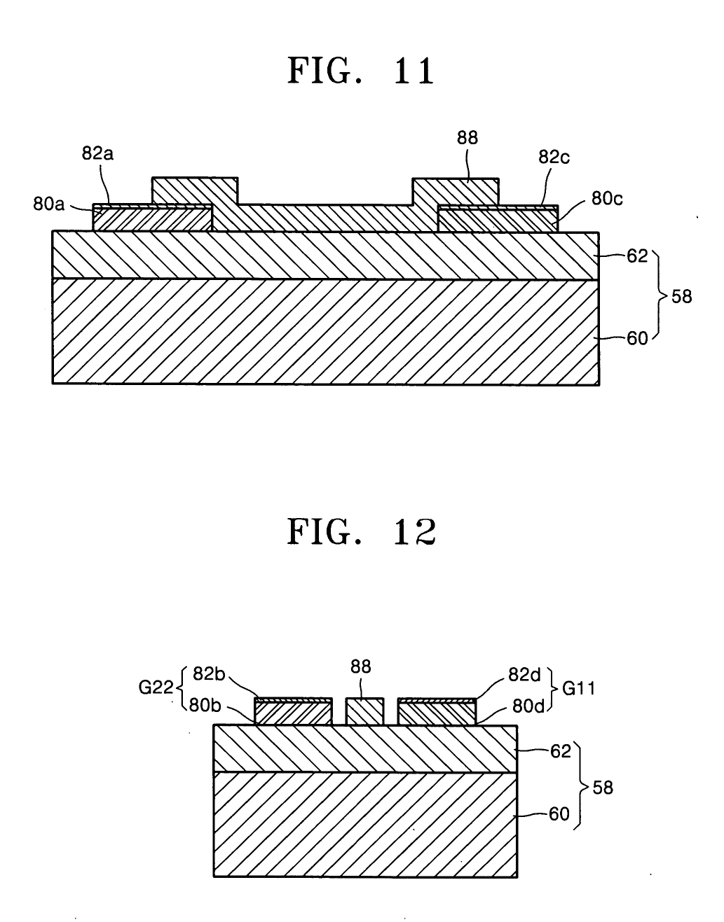

FIG. 11 is a sectional view taken along the line 11-11′ of FIG. 9.

Referring to FIG. 11, the source S1, the drain D1 and the channel layer 88 are all formed on a buffer layer 62. The source S1 includes first and second source conductive films 80a and 82a, which are deposited in sequence. The drain D1 includes first and second drain conductive films 80c and 82c, which are deposited in sequence. Additionally, the first gate G11 includes first and second gate conductive films 80d and 82d, which are deposited in sequence, and the channel layer 88 is extended on the source S1 and the drain D1. The first source conductive film 80a, the first drain conductive film 80c and the first gate conductive film 80d may be formed of chromium (Cr) as metal, but may be formed of a different metal such as molybdenum tungsten (MoW) or aluminum neodymium (AlNd). Additionally, the second source conductive film 82a, the second drain conductive film 82c and the second gate conductive film 82d may be formed of n⁺ doped amorphous silicon, for example.

FIG. 12 is a sectional view taken along the line 12-12′ of FIG. 9.

Referring to FIG. 12, the first and second gates G11 and G22 and the channel layer 88 have the same thickness. The first and second gates G11 and G22 and the channel layer 88 have a different thickness. For example, the first and second gates G1 and G22 may be thicker than the channel layer 88. The second gate G22 includes third and fourth gate conductive films 80b and 82b which are sequentially deposited. At this time, the third gate conductive film 80b may be formed identically with the first gate conductive film 80d of the first gate G11, and the fourth gate conductive film 82b may be formed identically with the second gate conductive film 82d.

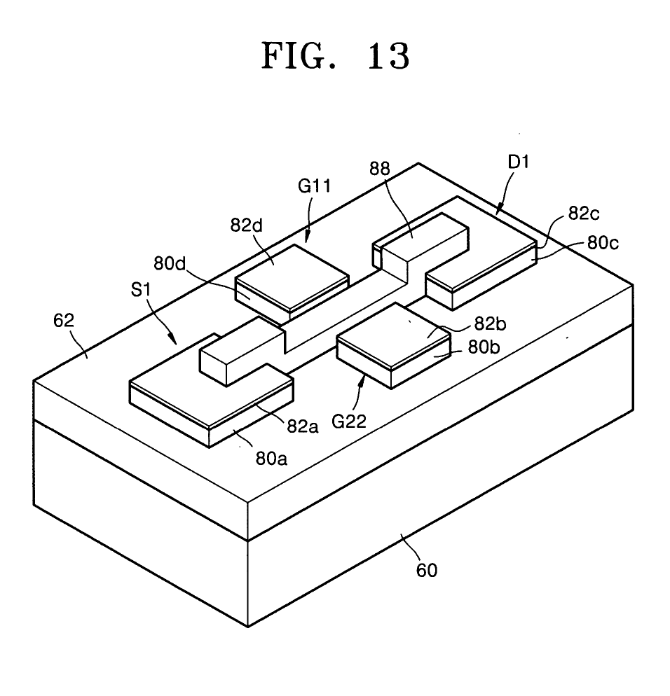

FIG. 13 is a perspective view illustrating the thin film transistor of FIG. 9.

Methods of manufacturing first and second TFTs by the present invention are described in the following.

### First Embodiment

The method of manufacturing the first TFT by the present invention is described in the following.

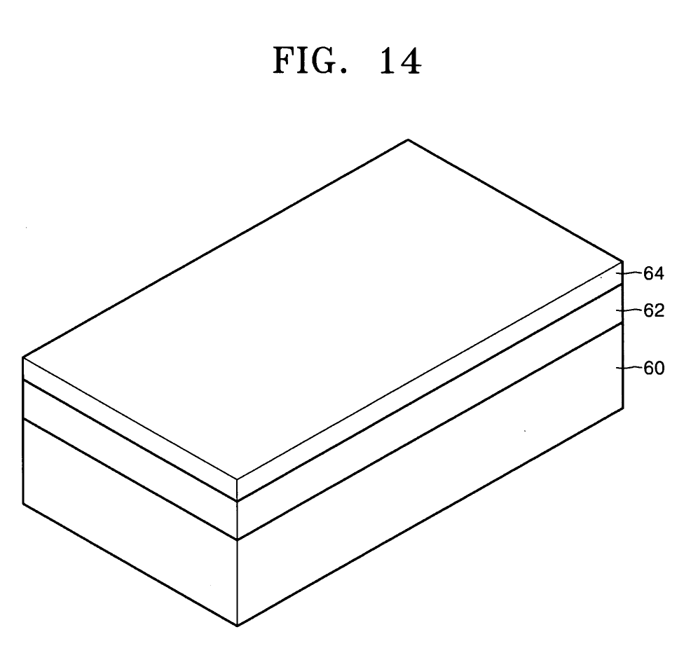

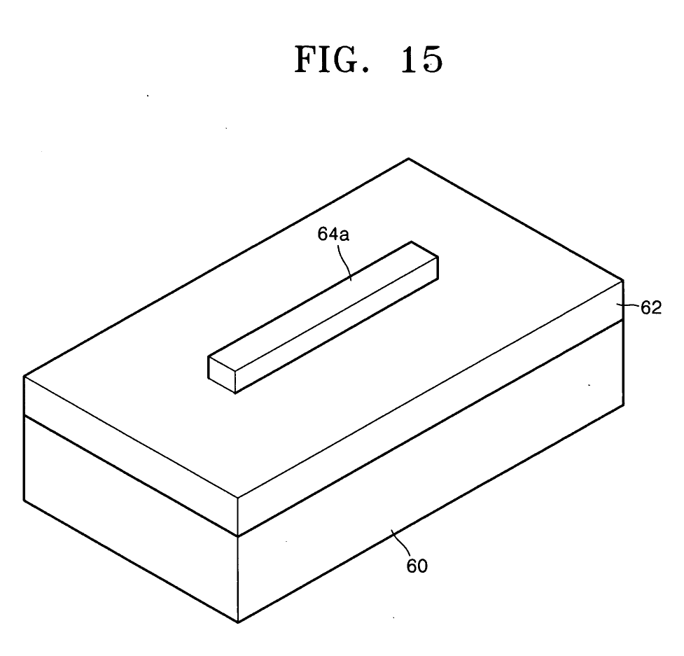

Referring to FIG. 14, the buffer layer 62 and a semiconductor layer 64 for forming the channel layer (64a of FIG. 8) are sequentially formed on the substrate 60. The substrate 60 may be a silicon substrate, but may also be one of a crystal substrate, an aluminum oxide substrate, a glass substrate and a plastic substrate. The buffer layer 62 can be formed of silicon oxide. The semiconductor layer 64 can be a silicon layer, for example, a single crystalline silicon layer. The single crystalline silicon layer is grown using an epitaxial growth method. Also, in order to form the single crystalline silicon layer, an amorphous silicon layer may be deposited and then laterally crystallized. The semiconductor layer 64 can be also formed of silicon germanium (SiGe) or germanium (Ge). The deposited semiconductor layer 64 is patterned to have the shape of the channel layer 64a as shown in FIG. 8 by using a photolithography process. In the photolithography process, a first mask is used to define a region for the channel layer 64a. Through the photolithography process, the channel layer 64a is formed on a predetermined region of the buffer layer 62 as shown in FIG. 15.

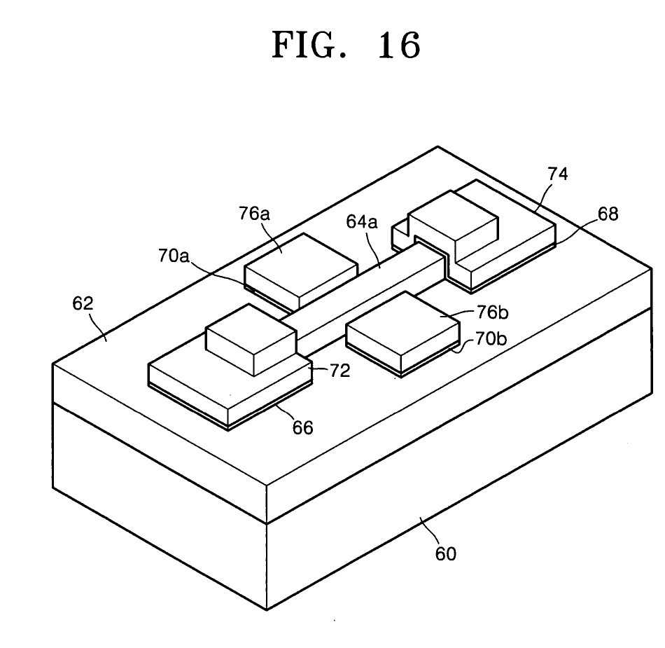

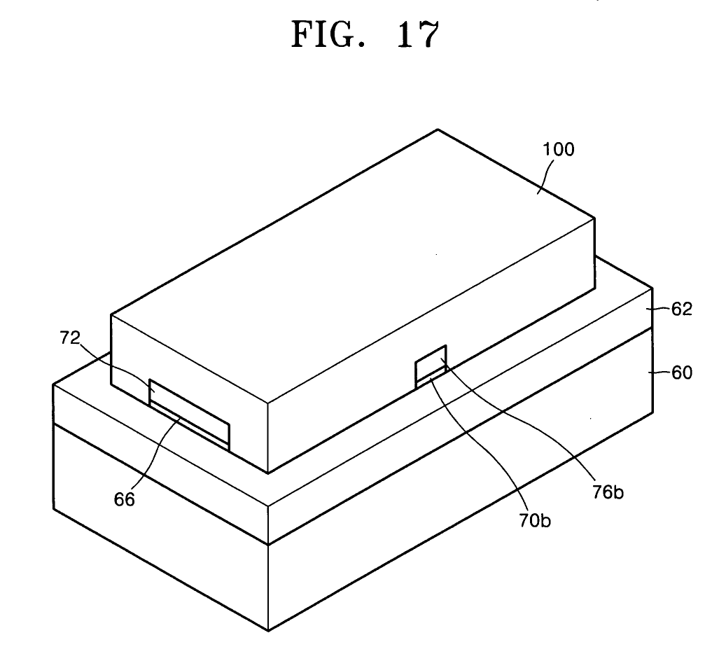

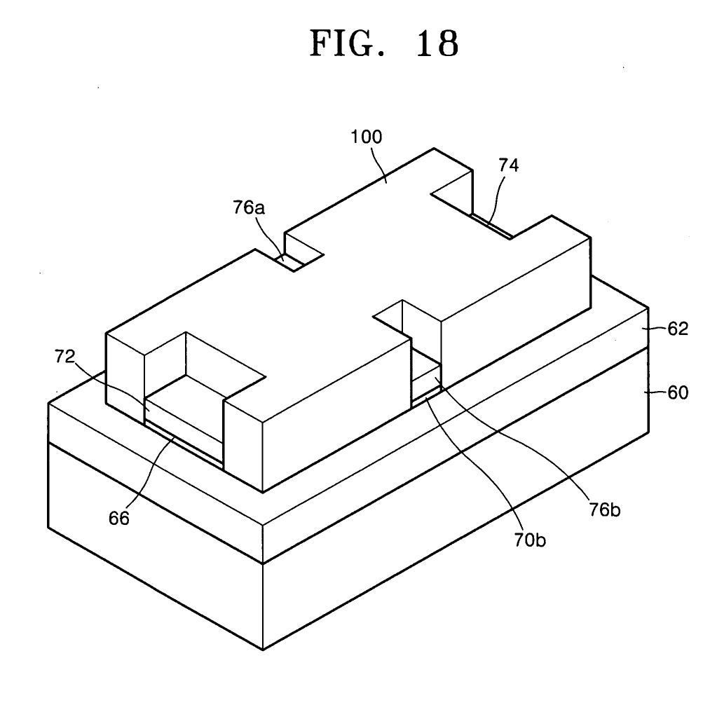

Referring to FIG. 16, first and second conductive films (not shown) are sequentially formed on the buffer layer 62 to cover the channel layer 64a. The first conductive film may be formed of a poly-silicon in which conductive impurities, for example, n+ type impurities are doped. The second conductive film may be formed of metal, for example, chromium (Cr). The second conductive film may be also formed of metal such as molybdenum tungsten (MoW) or aluminum neodymium (AlNd). After that, the first and second conductive films are sequentially etched using the photolithography process. In the photolithography process, a second mask is used to define a region for the gate G, the source S and the drain D of FIG. 16. As a result of etching the first and second conductive films by using the second mask, the source S and the drain D are respectively formed on the buffer layer 62 such that the portions of the source S and the drain D cover both ends of the channel layer 64a. Also, a gate G is formed. The gate G is spaced apart from the source S and the drain D and the channel layer 64a. The gate G is comprised of the first and second gates G1 and G2. The first and second gates G1 and G2 may be made symmetric centering on the channel layer 64a, but may be also asymmetric as shown in FIG. 5. The source S includes a first source conductive film 66 that is a first pattern of the first conductive film, and a second source conductive film 72 that is a first pattern of the second conductive film. The drain D includes the first drain conductive film 68 that is a second pattern of the first conductive film, and the second drain conductive film 74 that is a second pattern of the second conductive film. The first gate G1 includes the first gate conductive film 70a that is a third pattern of the first conductive film, and the second gate conductive film 76a that is a third pattern of the second conductive film. The second gate G2 includes the third gate conductive film 70b that is a fourth pattern of the first conductive film, and the fourth gate conductive film 76b that is a fourth pattern of the second conductive film.

After that, as shown in FIG. 17, an interlayer insulating layer 100 is formed on the buffer layer 62 to cover the channel layer 64a, the source S, the drain D, and first and second gates G1 and G2. The interlayer insulating layer 100 may be single-layered or multi-layered. When the interlayer insulating layer 100 is a multi-layer, the interlayer insulating layer 100 may be formed by sequentially depositing a silicon nitride film (SiN) and a silicon oxide film (SiO₂), and another insulating film may be additionally formed on the multi-layered interlayer insulating layer 100.

In the meantime, since all layers on the buffer layer 62 are covered with the interlayer insulating layer 100, they are not directly exposed to the external after the formation of the interlayer insulating film 100. However, FIG. 17 illustrates the third and fourth gate conductive films 70b and 76b and the first and second source conductive films 66 and 72 so that their side surfaces are exposed to the external for visual understanding.

Next, after the interlayer insulating layer 100 is formed, the interlayer insulating layer 100 is partly removed to expose some parts of the underlying source S, drain D, and first and second gates G1 and G2, thereby forming contacts of the source S, the drain D, and the first and second gates G1 and G2 as shown in FIG. 18. For this procedure, the photolithography process employing a third mask (not shown) is used to define the contact regions of the source S, the drain D, the first and second gates G1 and G2.

### Second Embodiment

The same members as those of the first embodiment use the same reference numerals, and descriptions thereof are omitted.

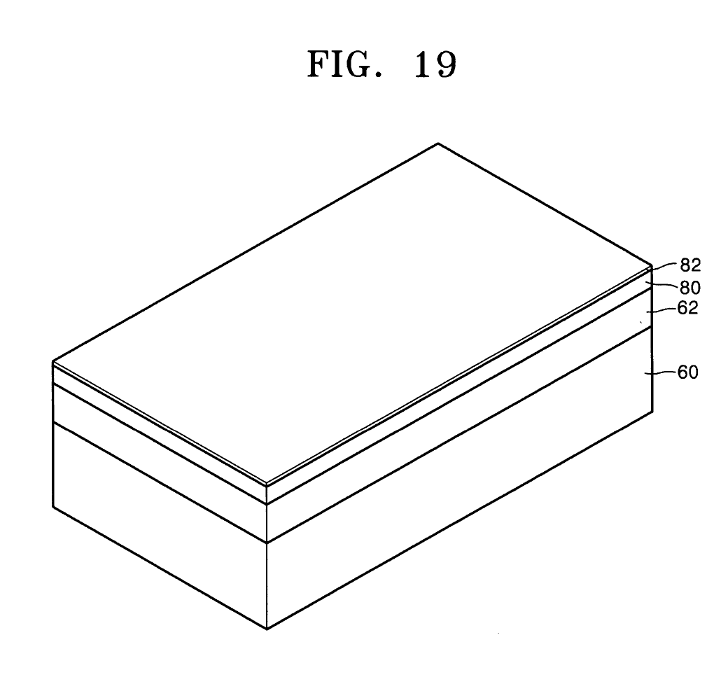

Referring to FIG. 19, the buffer layer 62 and the conductive film 80 are sequentially formed on the substrate 60. The conductive film 80 may be formed of chromium (Cr), molybdenum tungsten (MoW) or aluminum neodymium (AlNd). An n⁺ doped amorphous silicon film 82 is formed on the conductive film 80. After that, a predetermined photosensitive film pattern (not shown) is formed on the n⁺ doped amorphous silicon film 82 by using a photolithography process.

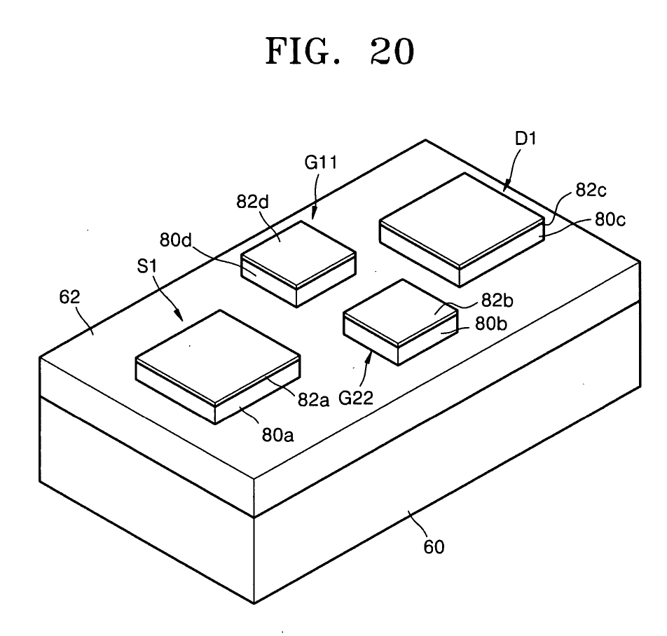

Describing in detail, a photosensitive film (not shown) is coated on the n⁺ doped amorphous silicon film 82 at a predetermined thickness and then, the coated photosensitive film is baked. Next, the substrate 60 is loaded on a stage of an exposure unit. Additionally, the first mask (not shown) is aligned to define the region for the source S1, the drain D1, and the first and second gates G11 and G22 of FIG. 20 on the baked photosensitive film. After the alignment of the first mask, light is irradiated on the entire surface of the first mask using the exposure unit. Next, the irradiated portion of the photosensitive film is removed to form the photosensitive film pattern (not shown) on the n⁺ doped amorphous silicon film 82. The photosensitive film pattern defines the region for the source S1, the drain D1, and the first and second gates G1 and G22 of FIG. 20. After the formation of the photosensitive film pattern, the resultant having the photosensitive film pattern is moved to a predetermined etching unit to sequentially etch the n⁺ doped amorphous silicon film 82 and the conductive film 80 by using the photosensitive film pattern as an etching mask. After the etching, the photosensitive film pattern is ashed and stripped for removal. Additionally, through a clean and dry process, the source S1, the drain D1 and the first and second gates G1 and G22 are formed on the buffer layer 62 according to the pattern of the first mask, as shown in FIG. 20. The first and second gates G11 and G22 may be formed to symmetrically face with each other. At this time, parts corresponding to the first and second gates G11 and G22 may be asymmetrically formed in the first mask, thereby forming the first and second gates G11 and G22 asymmetrically. Further, since the first and second gates G11 and G22 perform the same functions, both of them do not need to be formed. Accordingly, it does not matter that only any one of the first and second gates G11 and G22 is formed.

Referring to FIG. 20, the first and second source conductive films 80a and 82a are sequentially deposited to form the source S1, and the first and second drain conductive films 80c and 82c are sequentially deposited to form the drain D1. Additionally, the first and second gate conductive films 80d and 82d are sequentially deposited to form the first gate G11, and the third and fourth gate conductive films 80b and 82b are sequentially deposited to form the second gate G22. The first source conductive film 80a, the first drain conductive film 80c, the first gate conductive film 80d and the third gate conductive film 80b are respectively the first to fourth patterns of the first conductive film 80, which is formed by using the photolithography process. The second source conductive film 82a, the second drain conductive film 82c, the second gate conductive film 82d and the fourth gate conductive film 82b are respectively the first to fourth patterns of the n+ doped amorphous silicon film 82, which is formed by using the photolithography process.

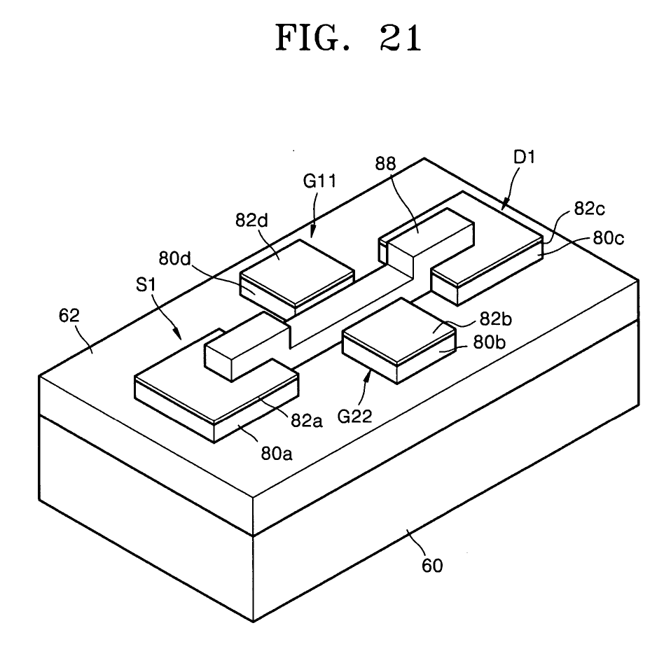

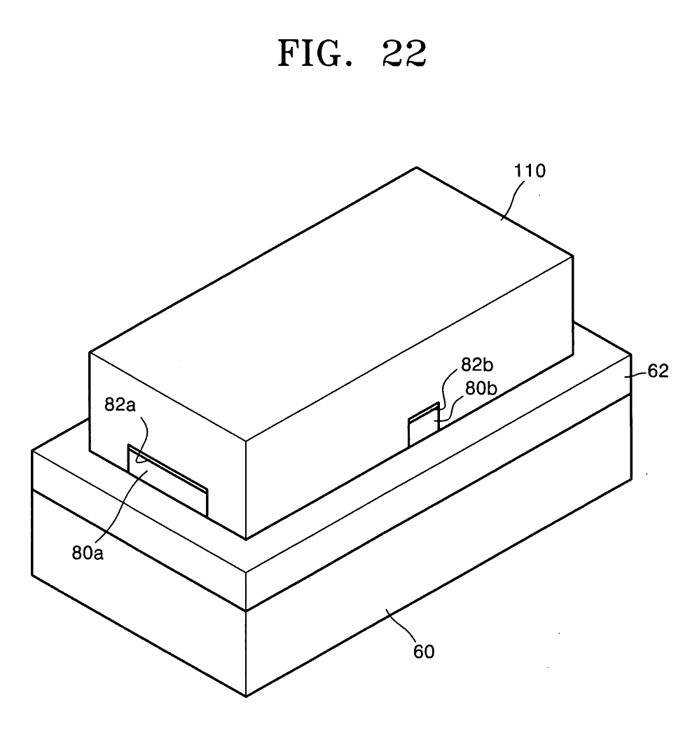

After the formation of the source S1, the drain D1, and the first and second gates G11 and G22 on the buffer layer 62, the channel layer 88 is formed on the buffer layer 62 between the source S1 and the drain D1 as shown in FIG. 21. The channel layer 88 is spaced apart from the first and second gates G11 and G22, and is extended on the source S1 and the drain D1. The channel layer 88 may be formed of doped poly-silicon, but may be also formed of silicon, silicon germanium or germanium.

In case where the doped poly-silicon layer is used as the channel layer 88, the channel layer 88 may be formed as follows.

In detail, the semiconductor layer (not shown) is formed on the buffer layer 62 to cover the source S1, the drain D1 and the first and second gates G11 and G22. At this time, the semiconductor layer may be a doped amorphous silicon layer or a doped poly-silicon layer. In case where the semiconductor layer is the doped amorphous silicon layer, the semiconductor layer is crystallized using a Solid-Phase Crystallization (SPC) method or a laser annealing method, for example, an Excimer Laser Annealing (ELA) method. After the crystallization of the semiconductor layer is completed, the semiconductor layer is patterned to have the same pattern as the channel layer 88 by using the same photolithography process as the source S1, the drain D1, the first and second gates G11 and G22. In this procedure, the second mask (not shown) is used to define a shape and a position of the channel layer 88.

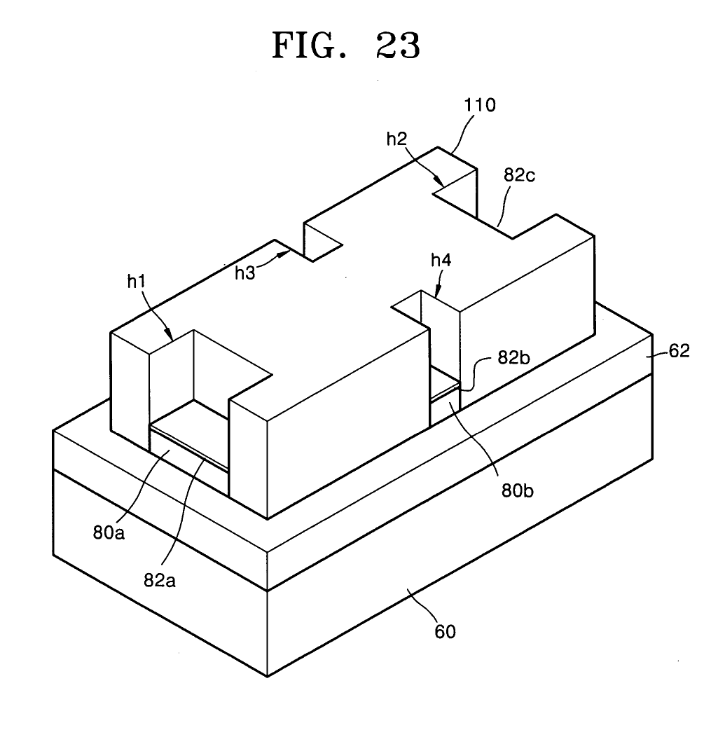

After the formation of the channel layer 88, an interlayer insulating layer 110 may be formed on the buffer layer 62 to fill a space between the first and second gates G11 and G22 and the channel layer 88 while covering the source S1, the drain D1, the first and second gates G11 and G22, and the channel 88. The interlayer insulating layer 110 may be formed with a single-layer or a multi-layer. When the interlayer insulating layer 110 is the multi-layer, the interlayer insulating layer 110 is formed by sequentially depositing the nitride film and the silicon oxide film, and another insulating film may be formed on the silicon oxide film. After the formation of the interlayer insulating layer 110, as shown in FIG. 23, first to fourth contact holes h1, h2, h3 and h4 may be formed in for the interlayer insulating layer 110 to expose each of the source S1, the drain D1 and the first and second gates G11 and G22 for contacts of the source S1, the drain D1 and the first and second gates G11 and G22. The first to fourth contact holes h1 to h4 are formed using a photolithography process. Therefore, when the first to fourth contact holes h1 to h4 are formed, the third mask (not shown) is used to define the position and the shape of the first to fourth contact holes h1 to h4. Subsequent processes can be performed in a general method.

As described above, in the TFT and method of manufacturing the TFT according to the present invention, two masks are used until the TFT is completed, and three masks inclusive of additional one mask are totally used if the contact holes for contacts of the source, the drain, and the gate are formed. Additionally, six processes are totally performed until the source, the drain and the gate are formed on the buffer layer to complete the TFT. Nine processes are totally performed if the contact holes are formed.

In the method of manufacturing the TFT according to the present invention, the number of used masks is reduced and the number of total processes is reduced in comparison with a conventional method. Therefore, the method of manufacturing the TFT according to the present invention has an effect in that a manufacture cost can be reduced. Additionally, since the source, the drain, the gate and the channel can be all formed on the same plane, they can be designed more flexibly. Further, the present invention can be also applied to a poly-silicon TFT, which is processed in a high temperature process.

While the present invention has been particularly shown and described with reference to exemplary embodiments thereof, it will be understood by those of ordinary skill in the art that various changes in form and details may be made therein without departing from the spirit and scope of the present invention as defined by the following claims. For example, the technical spirit for the formation of the source S or S1, the drain D or D1, and the first and second gates (G1 and G2) or (G11 and G22) on the same plane is employed while the first and second gates (G1 and G2) or (G11 and G22) can be connected across the channel layer 64a or 88. At this time, a gate insulating film can be formed between the first and second gates (G1 and G2) or (G11 and G22) and the channel. Also, the first and second gates (G1 and G2) or (G11 and G22) can be the same width and/or length, or different widths and/or lengths relative to each other.

1. A TFT (Thin Film Transistor) comprising:
a substrate;
a buffer layer formed on the substrate;
a source and a drain spaced apart from each other on the buffer layer;
a channel layer formed on the buffer layer to connect the source and the drain with each other; and
a gate formed on the buffer layer to be spaced apart from the source, the drain and the channel layer.

2. The TFT of claim 1, wherein the source comprises first and second source conductive films that are sequentially deposited.

3. The TFT of claim 1, wherein the drain comprises first and second conductive films that are sequentially deposited.

4. The TFT of claim 1, wherein the gate is comprised of first and second gates that are symmetric, centering on the channel layer, and at least any one of the first and second gates comprises two conductive films that are sequentially deposited.

5. The TFT of claim 1, wherein the channel layer is extended on the source and the drain.

6. The TFT of claim 1, wherein both ends of the channel layer are covered with portions of the source and the drain.

7. The TFT of claim 2, wherein the first source conductive film is n⁺ doped poly-silicon, and the second source conductive film is formed of one of chromium (Cr), molybdenum tungsten (MoW) and aluminum neodymium (AlNd).

8. The TFT of claim 2, wherein the first source conductive film is formed of one of chromium (Cr), molybdenum tungsten (MoW) and aluminum neodymium (AlNd), and the second source conductive film is formed of n⁺ doped poly-silicon.

9. The TFT of claim 3, wherein the first drain conductive film is formed of n⁺ doped poly-silicon, and the second drain conductive film is formed of one of chromium (Cr), molybdenum tungsten (MoW) and aluminum neodymium (AlNd).

10. The TFT of claim 3, wherein the first drain conductive film is formed of one of chromium (Cr), molybdenum tungsten (MoW) and aluminum neodymium (AlNd), and the second drain conductive film is formed of n⁺ doped poly-silicon.

11. The TFT of claim 4, wherein one of the two deposited conductive films is formed of n⁺ doped poly-silicon, and the other one is formed of one of chromium (Cr), molybdenum tungsten (MoW) and aluminum neodymium (AlNd).

12. The TFT of claim 1, wherein the channel layer is formed of one of silicon (Si), silicon germanium (SiGe) and germanium (Ge).

13. The TFT of claim 1, wherein an insulating film is provided between the gate and the channel layer.

14. The TFT of claim 1, wherein the gate is comprised of the first and second gates that are asymmetric centering on the channel layer.

15. The TFT of claim 14, wherein at least one of the first and second gates comprises the two conductive films that are sequentially deposited.

16. The TFT of claim 1, wherein the substrate is one of a crystal substrate, an aluminum oxide substrate, a glass substrate and a plastic substrate.

17. The TFT of claim 15, wherein the first gate and the second gate are disposed in the vicinities of the source and the drain, respectively.

18. A method of manufacturing a thin film transistor (TFT), the method comprising:
forming a buffer layer on a substrate;
forming a channel layer on the buffer layer;
forming a conductive film on the buffer layer to cover the channel layer; and
patterning the conductive film to form a source and a drain, which cover both ends of the channel layer, on the buffer layer and simultaneously form a gate to be spaced apart from the channel layer, the source and the drain.

19. The method of claim 18, wherein the conductive film is formed by sequentially first and second conductive films.

20. The method of claim 19, wherein the first conductive film is formed of n⁺ doped poly-silicon, and the second conductive film is formed of one of chromium (Cr), molybdenum tungsten (MoW) and aluminum neodymium (AlNd).

21. The method of claim 18, wherein the channel layer is formed of one of silicon (Si), silicon germanium (SiGe) and germanium (Ge).

22. The method of claim 18, wherein the gate is comprised of first and second gates.

23. The method of claim 22, wherein the first and second gates are symmetrically or asymmetrically formed centering on the channel layer.

24. The method of claim 18, further comprising:
forming an interlayer insulating layer which fills a space between the gate and the channel layer while covering the gate, the source and the drain; and
forming a contact hole for exposing the gate, the source and the drain in the interlayer insulating layer.

25. The method of claim 18, wherein the substrate is one of a crystal substrate, an aluminum oxide substrate, a glass substrate and a plastic substrate.

26. The method of claim 23, wherein the first gate is disposed closely to the source, and the second gate is disposed closely to the drain.

27. A method of manufacturing a thin film transistor (TFT), the method comprising:
forming a buffer layer on a substrate;
forming a conductive film on the buffer layer;
patterning the conductive film to separately form a source, a drain and a gate on the buffer layer; and
forming a channel layer for connecting the source with the drain on the buffer layer.

28. The method of claim 27, wherein the conductive film is formed by sequentially depositing first and second conductive films.

29. The method of claim of 27, wherein the forming of the channel layer further comprises:
forming an amorphous silicon film covering the gate, the source and the drain on the buffer layer;
crystallizing the amorphous silicon film; and
patterning the crystallized silicon film in a shape connecting the source with the drain.

30. The method of claim 29, wherein the amorphous silicon film is crystallized using a SPC (Solid-Phase Crystallization) method or an ELA (Excimer Laser Annealing) method.

31. The method of claim 28, wherein the first conductive film is formed of one of chromium (Cr), molybdenum tungsten (MoW) and aluminum neodymium (AlNd), and the second conductive film is formed of n⁺ doped poly-silicon.

32. The method of claim 27, wherein the channel layer is formed of one of silicon (Si), silicon germanium (SiGe) and germanium (Ge).

33. The method of claim 27, wherein the gate is comprised of first and second gates.

34. The method of claim 33, wherein the first and second gates are symmetrically or asymmetrically formed centering on the channel layer.

35. The method of claim 27, further comprising:
forming an interlayer insulating layer which fills a space between the gate and the channel layer while covering the gate, the source and the drain; and
forming a contact hole for exposing the gate, the source and the drain in the interlayer insulating layer.

36. The method of claim 27, wherein the substrate is one of a crystal substrate, an aluminum oxide substrate, a glass substrate and a plastic substrate.

37. The method of claim 34, wherein the first gate is disposed closely to the source, and the second gate is disposed closely to the drain.
